(19) United States
(12) Patent Application Publication
(10) Pub. No.: US 2011/0024838 A1
(43) Pub. Date: Feb. 3, 2011

(54) SEMICONDUCTOR DEVICE

(75) Inventors: Keigo KITAZAWA, Hino (JP); Junji Noguchi, Akishima (JP); Takayuki Oshima, Ome (JP); Shinichiro Wada, Fuchu (JP); Tomoyuki Miyoshi, Ome (JP); Atsushi Itoh, Fussa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/834,787

(22) Filed: Jul. 12, 2010

(30) Foreign Application Priority Data
Jul. 28, 2009 (JP) 2009-174894

(51) Int. Cl. H01L 27/06; H01L 29/78

(52) U.S. Cl. 257/337; 257/347; 257/499; 257/E27.014; 257/368; 257/E29.261

(57) ABSTRACT

There is provided a high withstand voltage LDMOS which is a MOS transistor formed on a semiconductor substrate and isolated by a trench, and a source region of which is sandwiched by a drain region, in which the metal layer gate wire connected to the gate electrode is led out outside the trench so as to pass over a P-type drift layer.

### CLAIM OF PRIORITY

The present application claims priority from Japanese patent application JP 2009-174894 filed on Jul. 28, 2009, the content of which is hereby incorporated by reference into this application.

### FIELD OF THE INVENTION

The present invention relates to an improvement in the reliability of a lateral diffused MOS (LDMOS) transistor (hereinafter simply referred to as LDMOS) having a high withstand voltage of 200 V to 600 V.

### BACKGROUND OF THE INVENTION

In recent years, in driver ICs for consumer and industrial appliances, there are demands for devices having various withstand voltages according to their applications, particularly, there are high demands for devices having a withstand voltage of 200 V to 600 V. It is essential for such a power device to secure reliability by sustaining a high voltage stress (of 200 V to 600 V) among a gate, a drain, and a source electrode at a high temperature of 100° C. or more according to its applications at a process of a reliability test.

FIG. 1 shows a cross section of a device structure of a related-art high-withstand voltage P channel LDMOS formed on an SOI substrate. The structure of a related-art high-withstand voltage P channel LDMOS is described below.

A semiconductor substrate is formed such that an N-type well diffusion layer 1 is formed on an N-type substrate or a P-type substrate and a field oxide film (Local Oxidation of Silicon: LOCOS) 2 for element isolation is formed on the surface of a partial region of the N-type well diffusion layer 1. A P-type buffer layer 6 is provided in a drain region to relax an electric field and reduce on-resistance. An N-type impurity is ion-injected and then the impurity is diffused by high temperature heat treatment to form a P channel 7. A gate electrode 4 is formed of poly-silicon on the field oxide film 2 to cause the field oxide film 2 to function as a gate oxide film. A P-type impurity is introduced with the field oxide film 2 as a mask to form a P-type high concentration diffusion layer 10 in a source and a drain region in a self-matching way. An N-type impurity used for supplying power to a well is introduced into a part of the source region to form an N-type high concentration diffusion layer 9.

A P-type low concentration diffusion layer 11 for relaxing an electric field is formed between the P-type (drain) high concentration diffusion layer 10 and the gate electrode 4. A trench isolation 8 for isolating dielectrics is formed in the N-type well diffusion layer 1 having a high resistance in such a manner as to encompass the high-withstand voltage P channel LDMOS. The trench isolation 8 reaches a buried oxide film 3 of the SOI substrate beneath the N-type well diffusion layer 1. Typically, the P-type low concentration diffusion layer 11 is an impurity diffusion layer and higher in concentration than the N-type well diffusion layer 1. The P-type low concentration diffusion layer 11 is expected to reduce the on-resistance and improve withstand voltage of the LDMOS.

A gate electrode 4 is formed on the field oxide film 2. Contact electrodes 33 are formed in the gate electrode, the source region, and the drain region. Furthermore, a first metal layer gate, source, and drain wires 12 to 14 are formed and a second metal layer gate, source, and drain wires 15 to 17 are formed.

FIG. 3 is a top view of the cross section shown in FIG. 1. In the related-art high-withstand voltage P channel LDMOS, a first metal layer drain wire 24 is led from the drain region and led by a second metal layer drain wire 21. A first metal layer source wire 26 is led from the source region and led by a second metal layer source wire 22. A first metal layer gate wire 25 is led from the gate region and led by a second metal layer gate wire 23 outside a trench isolation 27. The second metal layer gate wire 23 is provided across an N-type well diffusion layer 34 without passing over a P-type drift layer 28.

As a result, a high electric potential of 200 V to 600 V is generated across the metal layer gate wire and the N-type well diffusion layer 1 to cause a problem that an off withstand-voltage of the LDMOS is deteriorated after a stress test.

JP-A-Hei11(1999)-074518 relates to a trench-isolated high-withstand voltage PMOS and discusses a related-art example where a gate lead-out wire is provided in a drain region and an embodiment in which a drain region is formed of a contact P+ region and a low concentration P-type offset region. In the embodiment thereof, however, a source wire is provided beneath the gate wire and a lead-out wire is not provided on a low concentration injection layer (conduction type, similar to the drain region) in the high withstand voltage PMOS.

JP-A-2007-027358 relates to a trench-isolated high-withstand voltage PMOS and discusses an embodiment in which an electrode wire to which a high potential is applied does not cross an electrode wire to which a low potential is applied, however, a lead-out wire is not provided on a low concentration injection layer (conduction type, similar to the drain region) in the high withstand voltage PMOS.

JP-A-2005-251903 discusses an embodiment in which a gate electrode and a metal wire layer are alternately arranged to avoid the concentration of an electric field, realizing a high withstand voltage, however, a lead-out wire is not provided on a low concentration injection layer (conduction type, similar to the drain region) in the high withstand voltage PMOS.

JP-A-2003-068872 discusses an embodiment in which a plurality of plate electrodes in a floating state is formed to use a voltage allotment due to parasitic capacitance, however, a lead-out wire is not provided on a low concentration injection layer (conduction type, similar to the drain region).

### SUMMARY OF THE INVENTION

A high-withstand voltage driver IC can be used while maintaining a high voltage for a driving element for a long time from the viewpoint of its circuit function. The high-withstand voltage driver IC is subjected to a high temperature test in which such a state is maintained for a long time that an equal potential is applied across the source and the drain electrode and a high potential of 200 V to 600 V or more is applied to a gate electrode at a high temperature of 100° C. or more (a state where a channel is turned on), as a main stress condition, (such a high temperature bias test is referred to as ON-DCBL stress).

FIG. 4 shows the ON-DCBL stress in which a high voltage of 200 V to 600 V is applied to the source and the drain electrode 31 and 32 and the gate electrode is in a gate open state of 0 V(GND). In the arrangement of a related-art gate wire shown in FIG. 3, the metal layer gate wire of the high withstand voltage P-channel LDMOS is arranged in such a manner as to pass over the N-type well diffusion layer 1 and to be led out outside the trench, which causes a problem that the leak characteristic of an off withstand voltage is deteriorated by the ON-DCBL stress.

The present invention has been made in view of the above problems and has its object to provide a high withstand voltage LDMOS whose off withstand voltage deteriorated by the DCBL stress is improved.

To achieve the above object, the high withstand voltage LDMOS is characterized in that the LDMOS is formed on a semiconductor substrate, an element thereof is isolated by a trench, a source region is an LDMOS device sandwiched by a drain region, and the metal layer gate wire is led out outside the trench so as to pass over the P-type drift layer.

The semiconductor substrate is preferably an SOI substrate. High withstand voltage can be realized by the SOI substrate.

First Aspect of the Present Invention

(1) A semiconductor device in which a power semiconductor element and a logic circuit element are mounted on the same silicon substrate, wherein a MOS transistor used as the power semiconductor element includes: a channel diffusion layer encompassed by a trench for isolating an element and formed in a semiconductor substrate; a source high concentration diffusion layer formed in the channel diffusion layer; a drain high concentration diffusion layer formed at a spaced distance from the channel diffusion layer; a field oxide film formed between the source high concentration diffusion layer and the drain high concentration diffusion layer; a gate electrode formed on the field oxide film at a spaced distance from the drain high concentration diffusion layer; a field oxide film for relaxing a electric field formed under the side of the gate electrode on the side of the drain high concentration diffusion layer at a spaced distance from the channel diffusion layer; and a drain low concentration diffusion layer for relaxing a electric field between the drain high concentration diffusion layer and the gate electrode; wherein the metal layer gate wire connected to the gate electrode is led out in a hooked, rectangular, or curved shape outside the trench for isolating the element.

(2) In the above (1), the metal layer gate wire is preferably led out on the drain low concentration diffusion layer. The metal layer gate wire connected to the gate electrode passes over the drain low concentration diffusion layer to relax an electric field on a silicon interface, allowing the semiconductor device to withstand a higher voltage.

(3) In the above (1), the metal layer gate wire is preferably led out in a hooked or rectangular shape outside the trench and the longest portion of the metal layer gate wire is preferably led out on the drain low concentration diffusion layer. A rate at which the metal layer gate wire connected to the gate electrode passes over the drain low concentration diffusion layer is increased to relax an electric field on a silicon interface, allowing the semiconductor device to withstand a higher voltage.

(4) In the above (1), the MOS transistor preferably uses a thin thermal oxidation film formed on the source side as a gate oxide film. The use of a thin thermal oxidation film instead of a field oxide film allows forming an LDMOS few in impurity and high in reliability.

(5) In the above (4), the gate oxide film is preferably 100 nm or less in thickness. The thickness of the gate oxide film of 100 nm or less allows forming an LDMOS low in Vth.

(6) In the above (1), the metal layer gate wire preferably passes over the drain low concentration diffusion layer and is preferably led out outside the trench. The metal layer gate wire connected to the gate electrode passes over the drain low concentration diffusion layer to relax an electric field on a silicon interface, and the metal layer gate wire is led out outside the trench to lessen the further influence of electric field, allowing realizing a high withstand voltage.

(7) In the above (1) to (5), the LDMOS transistor is preferably formed on an SOI substrate and isolated by the trench. A voltage is allotted by the SOI substrate BOX and the trench to allow realizing a high withstand voltage.

Second Aspect of the Present Invention

(8) A high withstand voltage LDMOS which is a MOS transistor formed on a semiconductor substrate and isolated by a trench, and a source region of which is sandwiched by a drain region, wherein the metal layer gate wire connected to the gate electrode is led out outside the trench so as to pass over a P-type drift layer. If the drain region is located at the outer periphery of the source region, a large difference is generated in electric potential between the drain region and the outside of the trench when the device is used, producing a large effect of field relaxation.

(9) In the above (8), the metal layer gate wire is preferably led out over the P-type drift layer.

(10) In the above (8), the metal layer gate wire is preferably led out in a hooked or rectangular shape outside the trench and the longest portion of the metal layer gate wire is preferably led out on the P-type drift layer.

(11) In the above (8), the MOS transistor preferably uses a thin thermal oxidation film formed on the source region side as a gate oxide film.

(12) In the above (11), the gate oxide film is preferably 100 nm or less in thickness.

(13) In the above (8), the metal layer gate wire preferably passes over the P-type drift layer and is preferably led out outside the trench.

(14) In the above (8), the MOS transistor is preferably formed on an SOI substrate and isolated by the trench.

In the present invention, the gate wire is provided in such a manner as to pass over the P-type drift layer. As shown in FIG. 4, a voltage of 200 V to 600 V is applied to the gate electrode and a voltage of 0 V is applied to the source and the drain electrode at the time of ON-DCBL stress test, so that a high potential is generated between the metal layer gate wire and the SOI substrate. However, the P-type drift layer under the metal layer gate wire is depleted to relax the electric field, allowing realizing a high withstand voltage P channel LDMOS in which the deterioration of off withstand voltage performance due to the ON-DCBL stress is suppressed.

The present invention allows improving reliability of the LDMOS under a high electric field stress in the LDMOS having a high withstand voltage of 200 V to 600 V.

### BRIEF DESCRIPTION OF THE DRAWINGS

FIG. 1 is a cross section of a structure of a related-art high-withstand voltage P channel LDMOS;

FIG. 2 is a top view of a metal layer gate wire according to the present invention;

FIG. 3 is a top view of a related-art metal layer gate wire;

FIG. 4 is a schematic diagram of ON-DCBL stress test;

FIG. 5 is a cross section of a structure of a related-art high-withstand voltage N channel LDMOS;

FIG. 6 is a top view of a metal layer gate wire provided in a hooked shape;

FIG. 7 is a top view of a metal layer gate wire provided in a rectangular shape; and

FIG. 8 is a top view of a metal layer gate wire provided in a curved shape.

### DETAILED DESCRIPTION OF THE PREFERRED EMBODIMENTS

An embodiment of the present invention is described below with reference to drawings. Although the following description uses a high withstand voltage P channel LDMOS transistor as an example, an N conductivity MOS transistor obtained by reversing all polarities thereof in the structure can also be used. In the present invention, the semiconductor substrate refers to a concentration layer forming the channel inversion region of a MOS transistor and a region generally called a well of a MOS transistor including an epitaxially grown layer and a diffusion layer formed by ion implantation, as well as a silicon wafer.

### First Embodiment

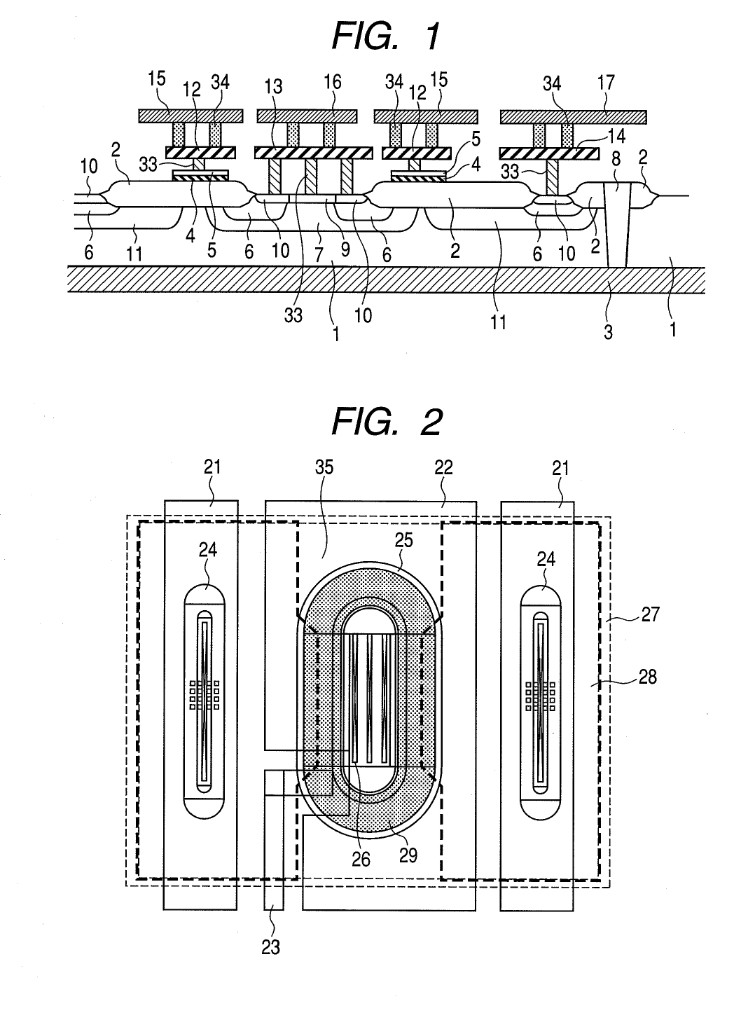

FIG. 1 shows a cross section of a device structure of a related-art high-withstand voltage P channel LDMOS. The configuration of the high-withstand voltage P channel LDMOS is described in detail below. The semiconductor substrate is configured such that an N-type well diffusion layer 1 is formed on an N-type substrate or a P-type substrate and a field oxide film 2 for element isolation is formed on the surface of a partial region of the N-type well diffusion layer 1. A bulk wafer or an SOI wafer having a buried oxide film 3 (Buried Oxide: BOX) is used as a wafer.

A P-type low concentration diffusion layer 11 for relaxing an electric field and reducing on-resistance is formed beneath the field oxide film 2 between the end of the gate electrode 4 on the drain side and the drain region. A P-type buffer layer 6 is provided in the drain region to relax an electric field. An N-type impurity is ion-injected into the gate electrode 4 from the source region and then the impurity is diffused by a high temperature heat treatment of 1000° C. or more to form a P channel 7. A gate poly-silicon being the gate electrode 4 and a gate cap oxide film 5 being a hard mask are formed. A resist is patterned by a lithography process and only the gate cap oxide film 5 is processed by dry etching. After that, the resist is removed and then the gate poly-silicon is processed with the gate cap oxide film 5 as the hard mask. The gate cap oxide film is used to form the gate electrode 4 of poly-silicon on the field oxide film 2, causing the field oxide film 2 to function as a gate oxide film. Furthermore, a P-type impurity is introduced with the field oxide film 2 as a mask to form a P-type high concentration diffusion layer 10 in the source and the drain region in a self-matching way. An N-type high concentration diffusion layer 9 is formed in the source region. This aims to supply the same voltage as biased that source region to the previously formed P channel 7.

After a diffusion process is formed, a first via electrode 33 is formed in the gate electrode 4 and a first metal layer gate wire 12 is formed thereon as a wire process. A second via electrode 34 is formed on the first metal layer gate wire 12. A second metal layer gate wire 15 is formed on the second via electrode 34.

Similarly, the first via electrode 33 is formed on the P-type high concentration diffusion layer 10 in the source region and a first metal layer source wire 13 is formed thereon. A second via electrode 34 is formed on the first metal layer source wire 13. A second metal layer source wire 16 is formed on the second via electrode 34. The first via electrode is, formed on the P-type high concentration diffusion layer 10 in the drain region and a first metal layer drain wire 14 is formed thereon. The second via electrode 34 is formed on the first metal layer drain wire 14. A second metal layer drain wire 17 is formed on the second via electrode 34.

FIG. 2 is a top view of wire layout shown in FIG. 1. FIG. 2 is described below. The second metal layer drain wire 21 shown in FIG. 2 corresponds to the second metal layer drain wire 17 shown in FIG. 1. Similarly, the second metal layer source wire 22 shown in FIG. 2 corresponds to the second metal layer source wire 16 shown in FIG. 1. The second metal layer gate wire 23 shown in FIG. 2 corresponds to the second metal layer gate wire 15 shown in FIG. 1. The first metal layer drain wire 24 shown in FIG. 2 corresponds to the first metal layer drain wire 12 shown in FIG. 1. The first metal layer source wire 21 shown in FIG. 2 corresponds to the first metal layer source wire 14 shown in FIG. 1. The first metal layer gate wire 25 shown in FIG. 2 corresponds to the first metal layer gate wire 12 shown in FIG. 1. The first metal layer source wire, 26 shown in FIG. 2 corresponds to the first metal layer source wire 13 shown in FIG. 1. The trench isolation 27 shown in FIG. 2 corresponds to the trench isolation 8 shown in FIG. 1. The P-type drift layer 28 shown in FIG. 2 corresponds to the P-type low concentration diffusion layer 11 shown in FIG. 1. An N-type well diffusion layer 35 shown in FIG. 2 corresponds to the N-type well diffusion layer 1 shown in FIG. 1.

In the present embodiment, as shown in FIG. 2, the second metal layer gate wire 23 lead out from the gate electrode is provided in such a manner as to pass over the P-type drift layer 28 and to be led out outside the trench.

As shown in FIG. 4, a high voltage of 200 V to 600 V is applied to the gate electrode and a voltage of 0 V is applied to the source and the drain electrode at the ON-DCBL stress, so that a high electric field is generated between the metal layer gate wire and the SOI substrate. However, the P-type drift layer under the metal layer gate wire is depleted to relax the electric field, allowing realizing a high withstand voltage P channel LDMOS in which the deterioration of off withstand voltage performance due to the ON-DCBL stress is suppressed.

### Second Embodiment

Another embodiment described below also provides an effect similar to that of the first embodiment, in which a metal layer gate wire is provided in an intentionally bent, hooked and rectangular shape on the plane surface and led out outside the trench and the wire portion of the metal layer gate wire shortest in a linear distance is provided so as to pass over the P-type drift layer.

### Third Embodiment

Furthermore, another embodiment also provides an effect similar to the effect provided by the first embodiment, in which a plurality of metal layer gate wire layers is formed and any of the gate wires is provided similarly to the first embodiment.

### Fourth Embodiment

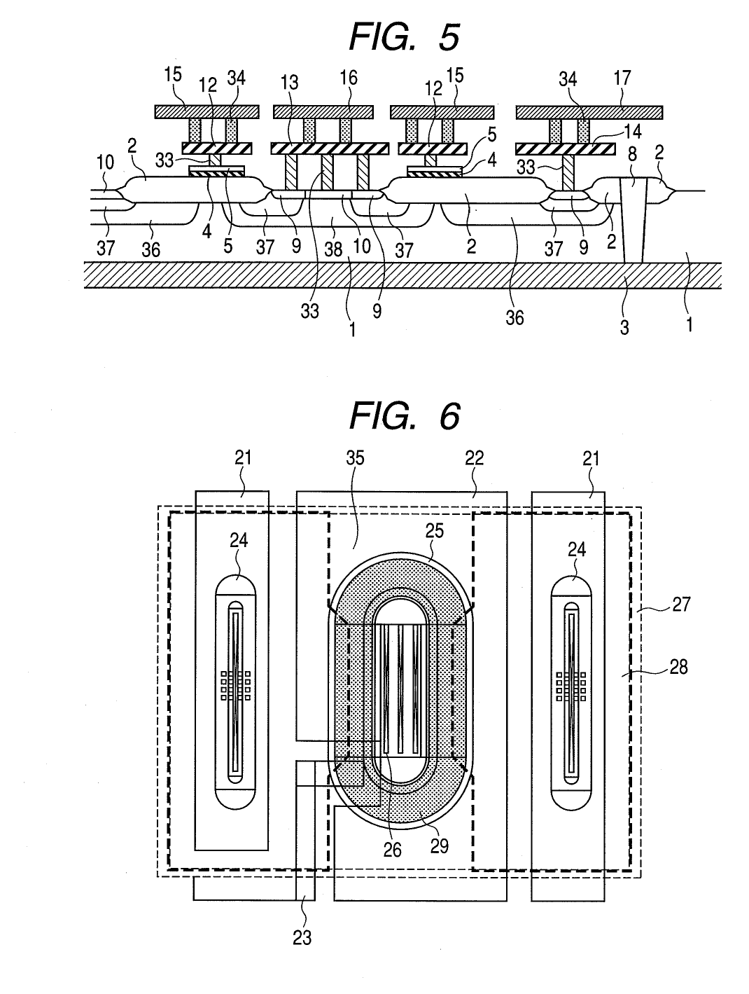

FIG. 5 shows an embodiment of an N conductivity MOS transistor. The N conductivity MOS transistor can be obtained by reversing all polarities of the structure described in FIG. 1. A configuration of a high withstand voltage N-channel LDMOS transistor is described in detail below.

The semiconductor substrate is configured such that an N-type well diffusion layer 1 is formed on an N-type substrate or a P-type substrate and a field oxide film 2 for element isolation is formed on the surface of a partial region of the N-type well diffusion layer 1. A bulk wafer or an SOI wafer having a buried oxide film 3 (BOX) is used as a wafer.

An N-type low concentration diffusion layer 36 for relaxing an electric field and reducing on-resistance is formed beneath the field oxide film 2 between the end of the gate electrode 4 on the drain side and the drain region. An N-type buffer layer 37 is provided in the drain region to relax an electric field. A P-type impurity is ion-injected into the gate electrode 4 from the source region and then the impurity is diffused by a high temperature heat treatment of 1000° C. or more to form an N channel 38. A gate poly-silicon being the gate electrode 4 and a gate cap oxide film 5 being a hard mask are formed. A resist is patterned by a lithography process and only the gate cap oxide film 5 is processed by dry etching. After that, the resist is removed and then the gate poly-silicon is processed with the gate cap oxide film 5 as the hard mask. The gate cap oxide film is used to form the gate electrode 4 of poly-silicon on the field oxide film 2, causing the field oxide film 2 to function as a gate oxide film. After that, a P-type impurity is introduced with the field oxide film 2 as a mask to form an N-type high concentration diffusion layer 9 in the source and the drain region in a self-matching way. Furthermore, a P-type high concentration diffusion layer 10 is formed in the source region. This aims to supply the same voltage as biased that source region to the previously formed P channel 7.

After a diffusion process is formed, a first via electrode 33 is formed in the gate electrode 4 and a first metal layer gate wire 12 is formed thereon as a wire process. A second via electrode 34 is formed on the first metal layer gate wire 12. A second metal layer gate wire 15 is formed on the second via electrode 34.

Similarly, the first via electrode 33 is formed on the P-type high concentration diffusion layer 10 in the source region and a first metal layer source wire 13 is formed thereon. A second via electrode 34 is formed on the first metal layer source wire 13. A second metal layer source wire 16 is formed on the second via electrode 34. The first via electrode is formed on the P-type high concentration diffusion layer 10 in the drain region and a first metal layer drain wire 14 is formed thereon. The second via electrode 34 is formed on the first metal layer drain wire 14. A second metal layer drain wire 17 is formed on the second via electrode 34.

The N conductivity MOS transistor can also provide effect similar to the effect obtained by the first embodiment.

### Fifth Embodiment

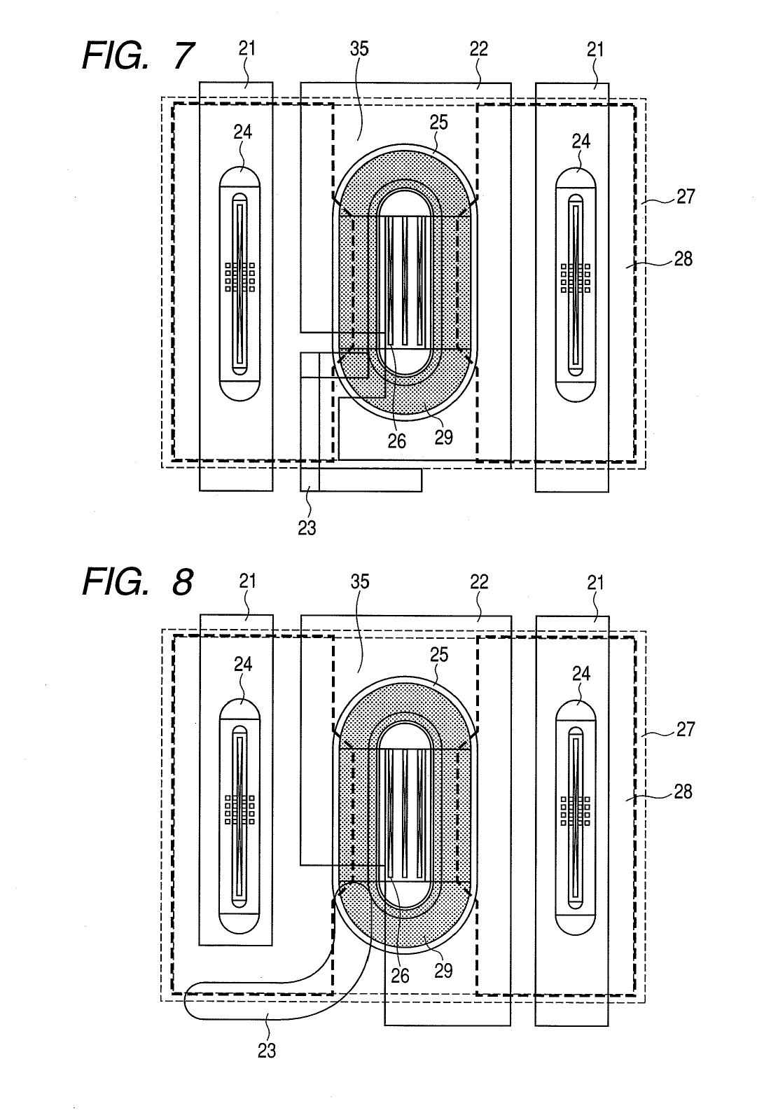

As shown in top layout views in FIGS. 6 and 7, such a structure may be used, as another embodiment, that the metal layer gate wire is led out in a hooked and rectangular shape outside the trench and the longest portion of the metal layer gate wire is led out on the drain low concentration diffusion layer.

### Sixth Embodiment

As shown in a top layout view in FIG. 8, such a structure may be used, as another embodiment, that the metal layer gate wire is led out in a curved shape outside the trench.

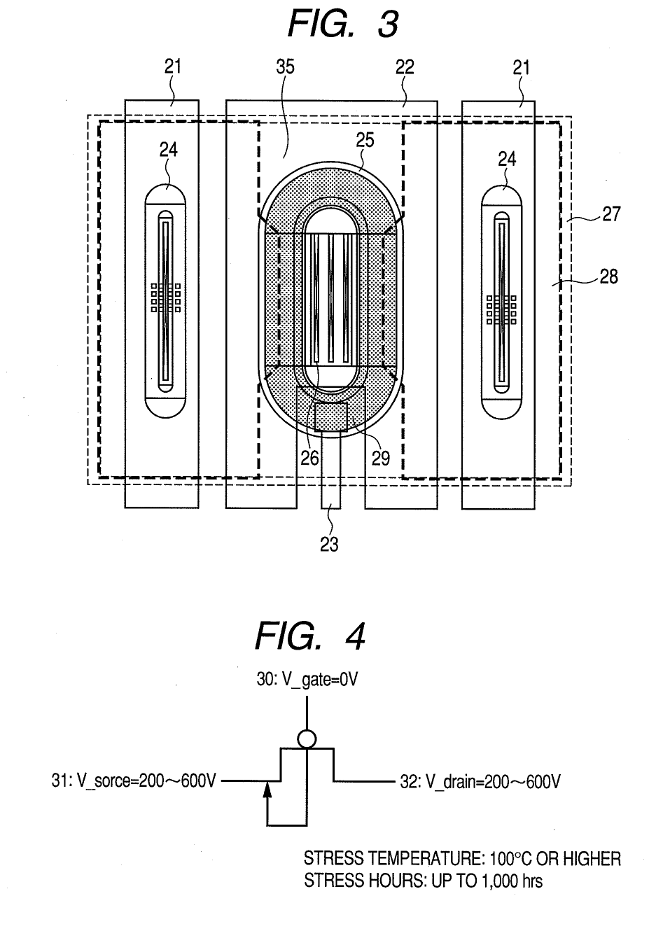

In the arrangement of a related-art gate wire shown in FIG. 3, although the metal layer gate wire of the high withstand voltage P-channel LDMOS is arranged in such a manner as to pass over the N-type well diffusion layer 1 and to be led out outside the trench, which causes a problem that the leak characteristic of an off withstand voltage is deteriorated by the ON-DCBL stress, the present invention can provide a high withstand voltage LDMOS whose off withstand voltage deteriorated by the DCBL stress is improved.

What is claimed is:

1. A semiconductor device in which a power semiconductor element and a logic circuit element are mounted on the same silicon substrate, wherein a MOS transistor used as the power semiconductor element comprises:
a channel diffusion layer encompassed by a trench for isolating an element and formed in a semiconductor substrate;
a source high concentration diffusion layer formed in the channel diffusion layer;
a drain high concentration diffusion layer formed at a spaced distance from the channel diffusion layer;
a field oxide film formed between the source high concentration diffusion layer and the drain high concentration diffusion layer;
a gate electrode formed on the field oxide film at spaced distance from the drain high concentration diffusion layer;
a field oxide film for relaxing a electric field formed under the side of the gate electrode on the side of the drain high concentration diffusion layer at a spaced distance from the channel diffusion layer; and
a drain low concentration diffusion layer for relaxing a electric field between the drain high concentration diffusion layer and the gate electrode;
wherein the metal layer gate wire connected to the gate electrode is led out in a hooked, rectangular, or curved shape outside the trench for isolating the element.

2. The semiconductor device according to claim 1, wherein
the metal layer gate wire is led out on the drain low concentration diffusion layer.

3. The semiconductor device according to claim 1, wherein
the metal layer gate wire is led out in a hooked or rectangular shape outside the trench and the longest portion of the metal layer gate wire is led out on the drain low concentration diffusion layer.

4. The semiconductor device according to claim 1, wherein
the MOS transistor uses a thin thermal oxidation film formed on the source side as a gate oxide film.

5. The semiconductor device according to claim 4, wherein
the gate oxide film is 100 nm or less in thickness.

6. The semiconductor device according to claim 1, wherein
the metal layer gate wire passes over the drain low concentration diffusion layer and is led out outside the trench.

7. The semiconductor device according to claim 1, wherein
the MOS transistor is formed on an SOI substrate and isolated by the trench.

8. A high withstand voltage LDMOS which is a MOS transistor formed on a semiconductor substrate and isolated by a trench, and a source region of which is sandwiched by a drain region,
wherein the metal layer gate wire connected to the gate electrode is led out outside the trench so as to pass over a P-type drift layer.

9. The semiconductor device according to claim 8, wherein
the metal layer gate wire is led out over the P-type drift layer.

10. The semiconductor device according to claim 8, wherein
the metal layer gate wire is led out in a hooked or rectangular shape outside the trench and the longest portion of the metal layer gate wire is led out on the P-type drift layer.

11. The semiconductor device according to claim 8, wherein
the MOS transistor uses a thin thermal oxidation film formed on the source region side as a gate oxide film.

12. The semiconductor device according to claim 11, wherein
the gate oxide film is 100 nm or less in thickness.

13. The semiconductor device according to claim 1, wherein
the metal layer gate wire passes over the P-type drift layer and is led out outside the trench.

14. The semiconductor device according to claim 8, wherein
the MOS transistor is formed on an SOI substrate and isolated by the trench.
